(19) United States
(12) Patent Application Publication
(10) Pub. No.: US 2001/0028266 A1
(43) Pub. Date: Oct. 11, 2001

(54) Method for adjusting phase of controlling clock signal and semiconductor integrated circuit having delay locked loop circuit

(75) Inventor: Nobutaka Taniguchi, Kawasaki (JP)

Correspondence Address: ARENT FOX KINTNER PLOTKIN & KAHN, PLLC, Suite 600, 1050 Connecticut Avenue, N.W., Washington, DC, 20036-5339, US

(73) Assignee: Fujitsu Limited

(21) Appl. No.: 09/827,241

(22) Filed: Apr. 6, 2001

(30) Foreign Application Priority Data
Apr. 7, 2000 (JP) 2000-106291

(51) Int. Cl. H03H 11/26

(52) U.S. Cl. 327/276

(57) ABSTRACT

A variable delay circuit generates a controlling clock signal by delaying a reference clock signal by a predetermined time. A dummy circuit delays the controlling clock signal by a predetermined time to generate a delayed clock signal. A phase comparator compares the delayed clock signal and the reference clock signal in phase. A delay control circuit adjusts the delay time of the variable delay circuit in accordance with a plurality of phase comparison results from the phase comparator, to have the delayed clock signal coincide with the reference clock signal in phase. Performing a single phase adjustment corresponding to a plurality of phase comparison results, prevents a delay in feeding back the controlling clock signal (delayed clock signal) transmitted through the dummy circuit to the phase comparator. This avoids extra operations of the delay control circuit and the variable delay circuit. Thus, jitter in the controlling clock signal is reduced.

### BACKGROUND OF THE INVENTION

1. Field of the Invention

The present invention relates to a method for adjusting the phase of a controlling clock signal to be implemented on a clock-synchronous semiconductor integrated circuit. The present invention also relates to a semiconductor integrated circuit on which a delay locked loop circuit is implemented.

2. Description of the Related Art

Among known semiconductor integrated circuits that operate in synchronization with a clock are SDRAMs (Synchronous DRAMs) and DDR-SDRAMs (Double Data Rate-Synchronous DRAMs). Semiconductor integrated circuits of this type operate their internal circuits in synchronization with a reference clock signal supplied from exterior, to input/output data. For example, read data is output over a period from time tLZ (output in Low-Z) to time tHZ (output in High-Z) after a rising edge of the reference clock signal. Typically, the minimum value of the time tLZ is set at 0 ns, so that the read data is output in synchronization with the rising edge of the reference clock signal.

By the way, there have been recently developed SDRAMs and DDR-SDRAMs that exceed 100 MHz in operating frequency. High speed memories of this type have the above-mentioned read data output period as short as several nanoseconds. Accordingly, it has become increasingly difficult to output read data constantly over a fixed period in synchronization with the reference clock signal, irrespective of variations in ambient temperature and fluctuations in power supply voltage.

Lately, there have been developed semiconductor integrated circuits that implement delay locked loop (DLL) circuits so that the output timing of read data is accurately synchronized to the reference clock signal to secure the output period with reliability. DLL circuits are circuits for adjusting the phase of a controlling clock signal for use in internal circuits to that of the reference clock signal supplied from exterior.

FIG. 1 shows an example of the DLL circuit to be implemented on a semiconductor integrated circuit such as an SDRAM.

The DLL circuit has an input buffer 2, a variable delay circuit 4, an output buffer 6, a dummy circuit 8, a phase comparator 10, and a delay adjustment circuit 12.

The input buffer 2 receives a reference clock signal RCLK supplied from exterior, amplifies the received signal, and outputs the resultant as a reference clock signal RCLK2. The variable delay circuit 4 generates a controlling clock signal CCLK which delays a predetermined time from the reference clock signal RCLK2. The output buffer 6 outputs read data that is read from a memory cell or the like in synchronization with the controlling clock signal CCLK. The read data is output to exterior as a data signal DT. The dummy circuit 8 generates a delayed clock signal CCLKD, which is the controlling clock signal CCLK delayed as much as the delay times of the input buffer 2 and the output buffer 6. The phase comparator 10 compares the reference clock signal RCLK2 and the delayed clock signal CCLKD in phase, and outputs the comparison result. The delay adjustment circuit 12 receives the result of the phase comparison by the phase comparator 10, and adjusts the delay time of the variable delay circuit 4.

FIG. 2 shows the general outline of the phase adjustment in the DLL circuit shown in FIG. 1.

The reference clock signal RCLK2 is generated with a delay by the delay time T1 of the input buffer 2 from the reference clock signal RCLK. The controlling clock signal CCLK is generated with a delay by the delay time T2 of the variable delay circuit 4 from the reference clock signal RCLK2. The data signal DT is output with a delay by the delay time T3 of the output buffer 6 from the controlling clock signal CCLK. Moreover, the delayed clock signal CCLKD is generated with a delay by the delay time T1+T3 of the dummy circuit 8 from the controlling clock signal CCLK.

Given that the reference clock signal RCLK2 and the delayed clock signal CCLKD coincide with each other in phase, one cycle of the reference clock signal RCLK2 is equal to the sum of the delay times T1, T2, and T3 of the input buffer 2, variable delay circuit 4, and output buffer 6. This allows the output timing of output data DOUT to coincide with a rising edge of the reference clock signal RCLK.

Meanwhile, the frequency of phase comparisons in the phase comparator 10 increases as the frequency of the reference clock signal RCLK becomes higher. A predetermined time is required to actually operate the delay adjustment circuit 12 upon comparing phase in the phase comparator 10 and change the delay time of the variable delay circuit 4. Therefore, when the reference clock signal RCLK has a higher frequency, the controlling clock signal CCLK (delayed clock signal CCLKD) modified in phase by the variable delay circuit 4 is fed back to the phase comparator 10 with some delay. It follows that the phase comparator 10 makes a comparison between the reference clock signal RCLK and the delayed clock signal CCLKD which have the same phase difference as the previous one. Here, the phase comparison result becomes identical to the previous one, and the delay adjustment circuit 12 performs an essentially needless, extra adjusting operation. Consequently, the phase variation amount of the controlling clock signal CCLK is never equal to the minimum unit of quantization in the DLL circuit, causing a problem of increasing jitter in the controlling clock signal CCLK. This phenomenon becomes more significant as the reference clock signal RCLK rises in frequency.

### SUMMARY OF THE INVENTION

An object of the present invention is to reduce jitter in a clock signal without increasing the scale of the DLL circuit.

Another object of the present invention is to optimally control the DLL circuit in accordance with the operating frequency, thereby reducing jitter in a clock signal.

According to one aspect of the present invention, a variable delay circuit generates a controlling clock signal by delaying a reference clock signal by a predetermined time. A dummy circuit delays the controlling clock signal by a predetermined time to generate a delayed clock signal. A phase comparator compares the delayed clock signal and the reference clock signal in phase. A delay control circuit receives a plurality of phase comparison results in sequence from the phase comparator. Corresponding to the plurality of phase comparison results identical to one another, the delay control circuit adjusts the delay time of the variable delay circuit to have the delayed clock signal coincide with the reference clock signal in phase.

As described above, the phase adjustment is not performed for every phase comparison, but one phase adjustment is performed corresponding to a plurality of phase comparison results. Therefore, a delay in feeding back the controlling clock signal (delayed clock signal) transmitted through the dummy circuit to the phase comparator is prevented, which avoids extra operations of the delay control circuit and the variable delay circuit. Thus, the amount of time of lead or delay in the phase of the controlling clock signal for a single phase adjustment is equal to the minimum unit adjustable by the variable delay circuit. As a result, jitter in the controlling clock signal is reduced.

According to another aspect of the present invention, the phase comparator outputs a lead or a delay in phase of the delayed clock signal to/from the reference clock signal in phase as a comparison result. The delay control circuit holds the plurality of comparison results in its plurality of holding parts, and when all the comparison results held are identical to one another, adjusts the delay time of the variable delay circuit. Since the delay time is adjusted in accordance with the logical operation on a plurality of comparison results, the delay control circuit is simplified in configuration.

According to another aspect of the present invention, the delay control circuit has a frequency divider for dividing the reference clock signal in frequency to generate a sampling clock signal. The delay control circuit adjusts the delay time of the variable delay circuit corresponding to the comparison result, which is synchronous to the sampling clock signal among the plurality of comparison results. Thus, the delay time is adjusted without the formation of holding circuits, operational circuits, or the like for receiving the comparison results.

According to another aspect of the present invention, a comparison setting unit is controlled for setting the dividing rate of the frequency divider to a predetermined value. That is, the number of comparison results necessary for performing a single adjustment of the variable delay circuit can be changed in accordance with the dividing rate of the frequency divider. Therefore, jitter in the controlling clock signal is minimized irrespective of the operating frequency.

According to another aspect of the present invention, the aforementioned predetermined value is set in a register capable of being set from the exterior and formed in the comparison setting unit. For example, a system device mounting a semiconductor integrated circuit accesses the register to set the predetermined value. In this case, the register is set at a predetermined value depending on the frequency of the system clock used during operation of the semiconductor integrated circuit.

According to another aspect of the present invention, the aforementioned predetermined value is changed in accordance with whether or not a fuse formed on the comparison setting unit is blown. For example, the predetermined value is set in accordance with the actual performance of a fabricated semiconductor integrated circuit, by blowing/unblowing the fuse depending on the maximum operating frequency evaluated in a probe test. This is particularly effective when semiconductor integrated circuits which are fabricated by using the same photomasks and semiconductor processes, are classified in accordance with their actual operating frequencies for shipment.

According to another aspect of the present invention, the aforementioned predetermined value is changed in accordance with the voltage on the destination of a conductive pattern formed on a semiconductor substrate in conformity to the pattern shape of the photomask used in a fabrication process. Thus, the predetermined value is set in accordance with the operating frequency characteristics of semiconductor integrated circuits shipped. This is particularly effective when semiconductor integrated circuits fabricated by using the same semiconductor processes, having a sufficient margin in operating frequency are shipped as a plurality of products adaptable to operating frequencies by mean of photomask switching.

According to another aspect of the present invention, the phase comparator outputs any one of a lead, delay, and coincidence of the delayed clock signal in phase to/from/with the reference clock signal in phase as the comparison results. The delay control circuit holds the plurality of comparison results in its plurality of holding parts, respectively. When the held comparison results include only either the leads or the delays, the delay control circuit adjusts the delay time of the variable delay circuit. Since the delay time is adjusted in accordance with the logical operation on a plurality of comparison results, the delay control circuit is simplified in configuration.

According to another aspect of the present invention, the phase comparator outputs a lead or a delay in phase of the delayed clock signal to/from the reference clock signal in phase as the comparison results. The delay control circuit counts the number of leads and the number of delays included in the plurality of comparison results by its counters, respectively, and compares the counted values of both counters to adjust the delay time of the variable delay circuit.

According to another aspect of the present invention, the comparison setting unit is controlled for setting the number of holding parts capable of holding the phase comparison results to a predetermined value. Therefore, the number of comparison results necessary for performing a single adjustment of the variable delay circuit can be changed in accordance with the operating frequency. Thus, jitter in the controlling clock signal is minimized regardless of the operating frequency.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a block diagram showing a semiconductor integrated circuit having a conventional DLL circuit;

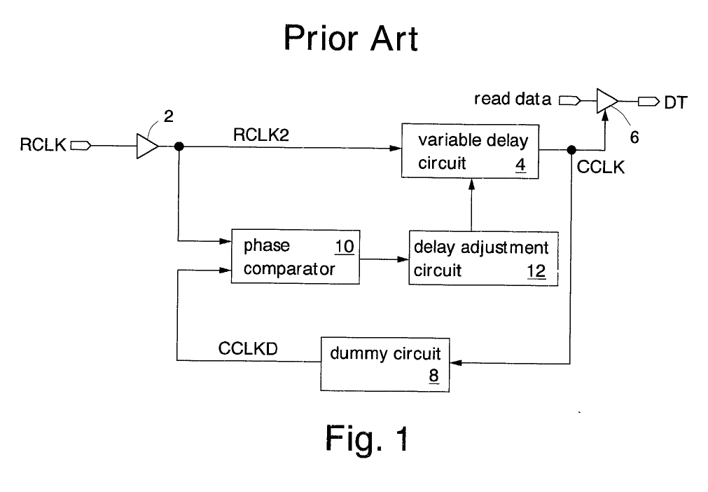

FIG. 2 is a block diagram showing the general outline of the phase adjustment in the conventional DLL circuit;

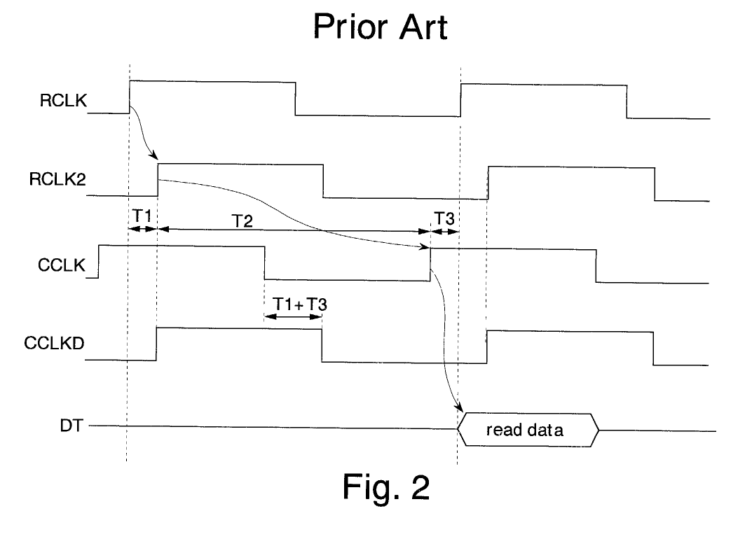

FIG. 3 is a block diagram showing the basic principles of the present invention;

FIG. 4 is a block diagram showing a first embodiment of the present invention;

FIG. 5 is a block diagram showing a second embodiment of the present invention;

FIG. 6 is a block diagram showing a third embodiment of the present invention; and

FIG. 7 is a block diagram showing a fourth embodiment of the present invention.

### DESCRIPTION OF THE PREFERRED EMBODIMENTS

Hereinafter, embodiments of the present invention will be described with reference to the drawings.

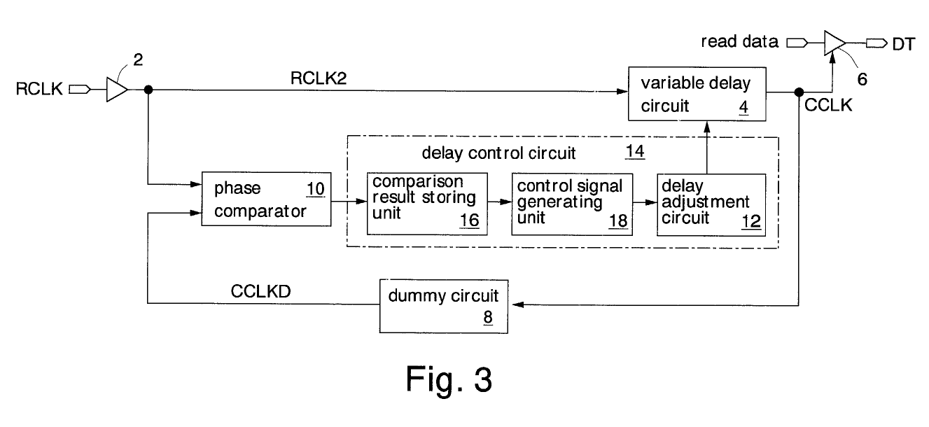

FIG. 3 shows the basic principles of a method for adjusting the phase of a controlling clock signal and a semiconductor integrated circuit having a delay locked loop (DLL) circuit in the present invention. The same circuits and signals as those described in the conventional art will be designated by identical reference numbers. Detailed description thereof will be O omitted.

The semiconductor integrated circuit has an input buffer 2, a variable delay circuit 4, an output buffer 6, a dummy circuit 8, a phase comparator 10, and a delay control circuit 14. The delay control circuit 14 comprises a comparison result storing unit 16, a control signal generating unit 18, and a delay adjustment circuit 12. Here, a DLL circuit corresponds to the portion excepting the input buffer 2 and the output buffer 6.

In this DLL circuit, the phase comparator 10, as in the conventional art, compares the phase of a reference clock signal RCLK2 output from the input buffer 2 with that of a delayed clock signal CCLKD output from the dummy circuit 8. The result of the phase comparison is once stored into the comparison result storing unit 16 before the information of a plurality of comparison results is collectively transmitted to the control signal generating unit 18. The control signal generating unit 18 controls the delay adjustment circuit 12 in accordance with this information, to adjust the delay time of the variable delay circuit 4. The frequency of operations by the delay adjustment circuit 12 and the variable delay circuit 4, or the number of times the comparison result storing unit 16 stores the comparison results, is determined in accordance with the operating frequency of the semiconductor integrated circuit. As a result, the frequency of controlling the variable delay circuit 4 can be adjusted to the time required for the feedback of the controlling clock signal CCLK to the phase comparator 10. This allows a reduction of the jitter in the controlling clock signal CCLK.

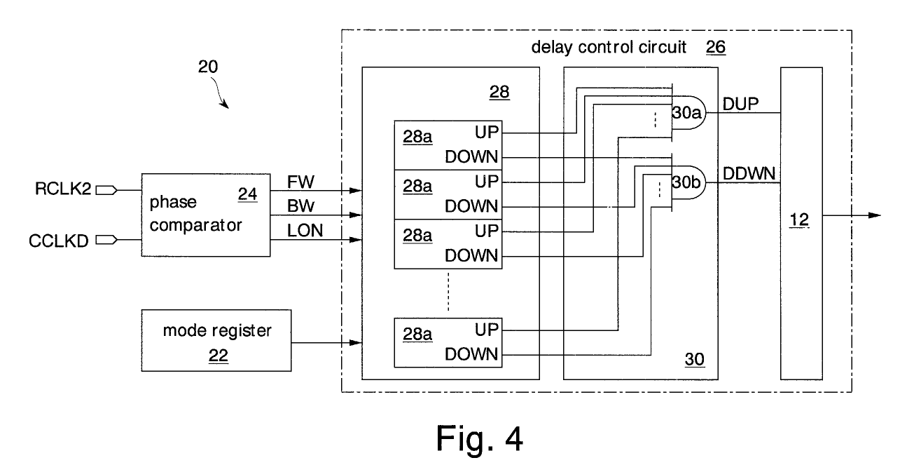

FIG. 4 shows a first embodiment of the method for adjusting the phase of a controlling clock signal and the semiconductor integrated circuit having a DLL circuit in the present invention. The same circuits and signals as those described in the conventional art will be designated by identical reference numbers. Detailed description will be omitted of these circuits and signals.

This semiconductor integrated circuit is formed as an SDRAM on a silicon substrate by using CMOS processes.

The SDRAM has a DLL circuit 20 and a mode register 22. Note that FIG. 4 shows only the essential parts of the invention. Aside from those shown in the diagram, the SDRAM also has input circuits, decoders, memory cores, control circuits for controlling the memory cores, output circuits, and so forth.

The DLL circuit 20 includes a phase comparator 24 and a delay control circuit 26. The delay control circuit 26 includes a storing register 28, a control signal generating unit 30, and a delay adjustment circuit 12.

The phase comparator 24 receives a reference clock signal RCLK2 and a delayed clock signal CCLKD, compares these signals in phase, and outputs the comparison result as any one of a backward signal BW, a forward signal FW, and a coincidence signal LON. Specifically, when the delayed clock signal CCLKD leads the reference clock signal RCLK2 in phase, the forward signal FW is activated. When the delayed clock signal CCLKD delays from the reference clock signal RCLK2 in phase, the backward signal BW is activated. When the delayed clock signal CCLKD coincides with the reference clock signal RCLK2 in phase, the coincidence signal LON is activated. Here, the coincidence in phase means that a phase difference between these signals RCLK2 and CCLKD becomes equal to or below the minimum delay time (minimum unit of quantization) adjustable by the variable delay circuit 4 shown in FIG. 3.

The storing register 28 has a plurality of holding parts 28a for holding a plurality of phase comparison results from the phase comparator 24, respectively. These holding parts 28a are successively activated by a pointer (not shown) which shifts in synchronization with the phase comparisons. The pointer-pointed holding part 28a, upon receiving the activation of the forward signal FW, turns its terminal UP to high level and its terminal DOWN to low level. The pointer-pointed holding part 28a, on receiving the activation of the backward signal BW, turns the terminal DOWN to high level and the terminal UP to low level. Moreover, the pointer-pointed holding part 28a, on receiving the activation of the coincidence signal LON, turns both the terminals UP and DOWN to low level. After the pointer points at the last holding part 28a, the holding parts 28a are inactivated to turn their terminals UP and DOWN both to low level.

The control signal generating unit 30 has an AND gate 30a for receiving the signals output from the terminals UP of the holding parts 28a and an AND gate 30b for receiving the signals output from the terminals DOWN of the holding parts 28a. The AND gate 30a outputs a shift-up signal DUP of high level when all the terminals UP are at high level. The AND gate 30b outputs a shift-down signal DDWN of high level when all the terminals DOWN are at high level.

The delay adjustment circuit 12 increases the delay time of the variable delay circuit 4 shown in FIG. 3 when it receives the shift-up signal DUP. The delay adjustment circuit 12 decreases the delay time of the variable delay circuit 4 when it receives the shift-down signal DDWN. That is, the delay adjustment circuit 24 operates corresponding to the plurality of phase comparison results from the phase comparator 24, adjusting the delay time of the variable delay circuit 4. Therefore, the phase adjustment is performed optimally in synchronization with the feedback timing of the controlling clock signal CCLK to the phase comparator 24.

The mode register 22 is a register capable of being set from chip exterior. In accordance with the operating frequency of the SDRAM, a predetermined value is set in the mode register 22. This changes the number of holding parts 28a to be activated, thereby changing the number of phase comparisons necessary for a delay adjustment. For example, in the case of adjusting the delay time of the variable delay circuit 4 corresponding to four successive phase comparison results, four holding parts 28a are activated. Here, the pointer successively points at the four holding parts 28a in synchronization with the phase comparisons. The four holding parts 28a hold the phase comparison results until the pointer is reset and, at the same time, the information held in the holding parts 28a are reset. That is, the mode register 22 functions as the comparison setting unit which sets the number of holding parts 28a for holding the phase comparison results to a predetermined value.

The value set in the mode register 22 is determined in accordance with the operating frequency of the semiconductor integrated circuit. Then, the frequency of controlling the variable delay circuit 4 is adjusted to the time required for the feedback of the controlling clock signal CCLK to the phase comparator 24. This reduces the jitter in the controlling clock signal CCLK. Specifically, the mode register 22 is set to a predetermined value depending on the frequency of the system clock used during operation of the semiconductor integrated circuit.

In this connection, a fuse circuit may be formed on the SDRAM so that the number of holding parts 28a to be activated is changed by means of fuse blowing, not by the mode register 22. In SDRAM fabrication, a plurality of photomasks having different pattern shapes may be prepared in the wiring process so that the number of holding parts 28a to be activated is changed in accordance with the destinations of conductive patterns, not by the mode register 22.

As has been described, in the present embodiment, one adjustment of delay time is performed corresponding to a plurality of phase comparisons. This allows the variable delay circuit 4 to operate corresponding to a time required for the feedback of the controlling clock signal CCLK to the phase comparator 24. Thus, the amount of lead or delay in the phase of the controlling clock signal CCLK in a single phase adjustment can be rendered as the minimum unit adjustable by the variable delay circuit 4. As a result, the jitter in the controlling clock signal can be reduced.

When all the comparison results held in the holding parts 28a of the storing register 28 are identical, the delay time of the variable delay circuit 4 is adjusted corresponding to the comparison results. Since the delay time can be adjusted in accordance with the logical operation on a plurality of comparison results, the delay control circuit 26 can be simplified in configuration. Conventionally, the frequency of operating the variable delay circuit 4 was lowered by dividing the frequencies of the reference clock signal RCLK2 and the delayed clock signal CCLKD with the respective frequency dividers and subjecting the frequency-divided clock signals to phase comparison. As compared with the above-described conventional example, the present embodiment allows a significant reduction in circuit scale.

The mode register 22 capable of being set from exterior is used to set the number of holding parts 28a to be activated, or the number of phase comparisons necessary for a single adjustment to the variable delay circuit 4. Therefore, the set value of the mode register 22 can be changed to minimize the jitter in the controlling clock signal CCLK, regardless of the operating frequency.

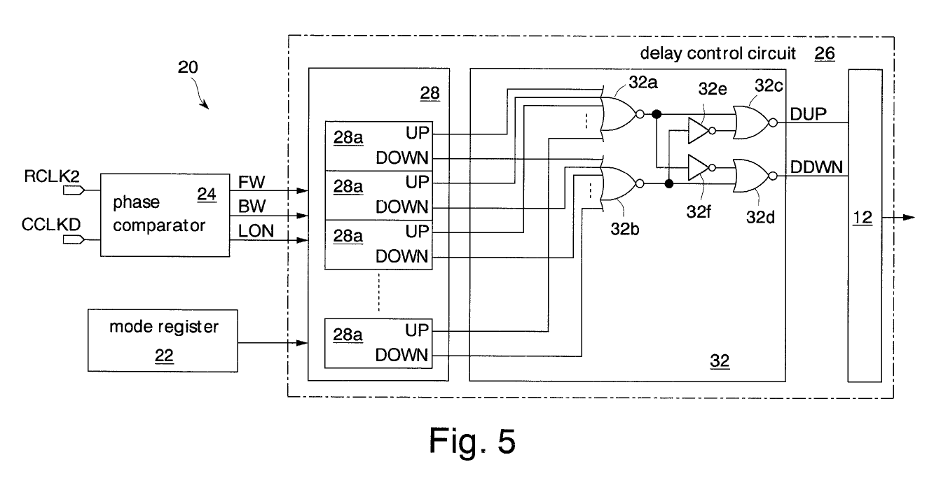

FIG. 5 shows a second embodiment of the method for adjusting the phase of a controlling clock signal and the semiconductor integrated circuit having a DLL circuit in the present invention. The same circuits and signals as those described in the conventional art and in the first embodiment will be designated by identical reference numbers. Detailed description thereof will be omitted.

In this embodiment, a control signal generating unit 32 in the delay control circuit 26 differs from the control signal generating unit 30 of the first embodiment. The other configuration is identical to that of the first embodiment.

The control signal generating unit 32 has NOR gates 32a, 32b, 32c, and 32d, along with inverters 32e and 32f. The NOR gate 32a receives the signals output from the terminals UP of the holding parts 28a. The NOR gate 32b receives the signals output from the terminals DOWN of the holding parts 28a. The NOR gate 32c receives the output of the NOR gate 32a and, through the inverter 32e, the output of the NOR gate 32b. The NOR gate 32c outputs a shift-up signal DUP. The NOR gate 32d receives the output of the NOR gate 32b and, through the inverter 32f, the output of the NOR gate 32a. The NOR gate 32d outputs a shift-down signal DDWN.

The shift-up signal DUP is turned to high level when any of the holding parts 28a holds the information of the forward signal FW and none holds the information of the backward signal BW. The shift-down signal DDWN is turned to high level when any of the holding parts 28a holds the information of the backward signal BW and none holds the information of the forward signal FW. In other words, the shift-up signal DUP is turned to high level when the holding parts 28a hold the information of the forward signal FW and the coincidence signal LON, or when all the holding parts 28a hold the information of the forward signal FW. Similarly, the shift-down signal DDWN is turned to high level when the holding parts 28a hold the information of the backward signal BW and the coincidence signal LON, or when all the holding parts 28a hold the information of the backward signal BW.

Similarly to the first embodiment, the number of holding parts 28a to be activated can be changed by the mode register 22. That is, the mode register 22 functions as the comparison setting unit which sets the number of holding parts 28a for holding the phase comparison results, to a predetermined value.

In this connection, a fuse circuit may be formed on the SDRAM so that the number of holding parts 28a to be activated is changed by means of fuse blowing, not by the mode register 22. In SDRAM fabrication, a plurality of photomasks having different pattern shapes may be prepared in the wiring process so that the number of holding parts 28a to be activated is changed in accordance with the destinations of conductive patterns, not by the mode register 22.

This embodiment can offer the same effect as that obtained from the first embodiment described above. That is, the jitter in the controlling clock signal CCLK can be reduced by the delay control circuit 26 in simple configuration.

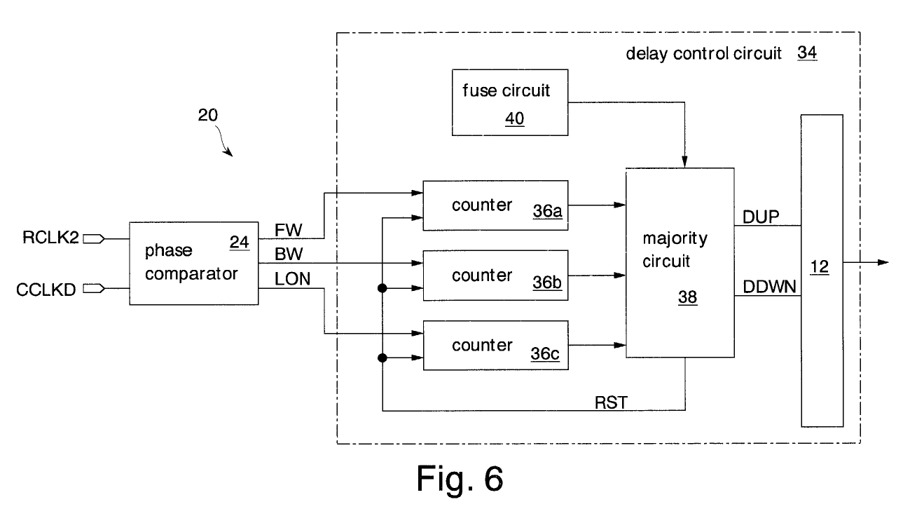

FIG. 6 shows a third embodiment of the method for adjusting the phase of a controlling clock signal and the semiconductor integrated circuit having a DLL circuit in the present invention. The same circuits and signals as those described in the conventional art and in the first embodiment will be designated by identical reference numbers. Detailed description thereof will be omitted.

In this embodiment, a delay control circuit 34 differs from the delay control circuit 26 of the first embodiment. Moreover, this embodiment includes no mode register. The other configuration is identical to that of the first embodiment.

The delay control circuit 34 comprises counters 36a, 36b, and 36c which count up in response to the forward signal FW, the backward signal BW, and the coincidence signal LON, respectively. The delay control circuit 34 also includes a majority circuit 38 for receiving the counts of these counters 36a, 36b, and 36c, along with a fuse circuit 40.

The counters 36a, 36b, and 36c count the numbers of times the signals FW, BW, and LON are activated, respectively, while a reset signal RST is inactivated. The counters are reset by the activation of the reset signal RST.

Subsequent to a plurality of phase comparisons by the phase comparator 24, the majority circuit 38 performs a majority operation on the counts of the counters 36a, 36b, and 36c, to output the shift-up signal DUP or the shift-down signal DDWN. Specifically, when the count of the counter 36a is the greatest, the shift-up signal DUP is activated. When the count of the counter 36b is the greatest, the shift-down signal DDWN is activated. If the count of the counter 36c is the greatest, or the counts of the counters 36a and 36b are equal, then the reference clock signal RCLK and the delayed clock signal CCLKD are determined to coincide with each other in phase. Here, neither the shift-up signal DUP nor the shift-down signal DDWN is activated. Moreover, when the counts of the counters 36a and 36c are equal to each other and are greater than the count of the counter 36b, the shift-up signal DUP is activated. Here, the shift-up signal DUP may be inactivated instead. When the counts of the counters 36b and 36c are equal to each other and are greater than the count of the counter 36a, the shift-down signal DDWN is activated. Here, the shift-down signal DDWN may be inactivated instead. After the majority operation, the majority circuit 38 activates the reset signal RST to reset the counters 36a, 36b, and 36c.

The fuse circuit 40 is a circuit for setting the output timing of the reset signal RST which the majority circuit 38 outputs. The fuse circuit 40 has fuses made of polysilicon or the like. The fuses are blown to determine the inactive period of the reset signal RST. The inactive period of the reset signal RST indicates the number of comparisons by the phase comparator 24 required for the majority circuit 38 to perform a majority operation. For example, two fuses can be formed to set the number of comparisons for a majority operation to four, six, eight, or ten. That is, in this embodiment, the maximum counts of the counters 36a, 36b, and 36c for the majority circuit 38 of the delay control circuit 34 to receive are set by means of fuse blowing. Then, the fuse circuit 40 functions as the comparison setting unit for setting the number of phase comparison results.

Here, the fuse blowing is applied, for example, to all the chips in the same manufacturing lot as that a chip evaluated for the operating frequency belongs to. In the present embodiment, the fuse blowing can be performed on a chip-by-chip basis. Thus, the number of comparisons may also be set in accordance with the operating frequency characteristics which are dependent on the positions of the chips on wafers or the positions of the wafers within a manufacturing lot.

Incidentally, a register capable of being set from chip exterior may be formed on the SDRAM so that the number of phase comparison results is set by the register, not by the fuse circuit 40. Alternatively, in SDRAM fabrication, a plurality of photomasks having different pattern shapes may be prepared in the wiring process so that the number of phase comparisons is set in accordance with the destinations of conductive patterns, not by the fuse circuit 40.

This embodiment can offer the same effect as that obtained from the first embodiment. Besides, in this embodiment, the formation of the counter 36a, 36b, and 36c and the majority circuit 38 allows the variable delay circuit 4 to operate corresponding to the time required for the feedback of the controlling clock signal CCLK to the phase comparator 24.

Moreover, the number of phase comparisons required for a single adjustment to the variable delay circuit 4 is changed depending on whether or not the fuses of the fuse circuit 40 are blown. Therefore, the number of phase comparisons can be set in accordance with the actual performance of the SDRAM, evaluated in a testing process. This embodiment is particularly effective when semiconductor integrated circuits fabricated by using the same photomasks and semiconductor manufacturing processes are classified for shipment depending on their actual operating frequencies.

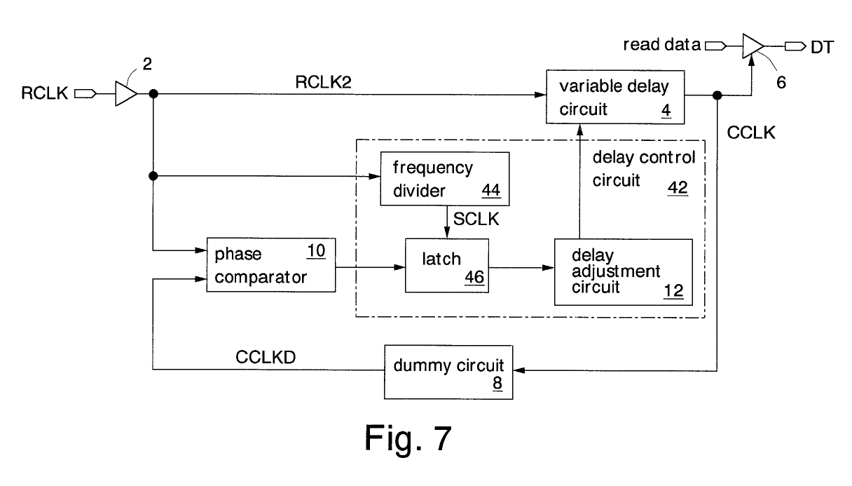

FIG. 7 shows a fourth embodiment of the method for adjusting the phase of a controlling clock signal and the semiconductor integrated circuit having a DLL circuit in the present invention. The same circuits and signals as those described in the conventional art and in the first embodiment will be designated by identical reference numbers. Detailed description thereof will be omitted.

In this embodiment, a delay control circuit 42 differs from the delay control circuit 26 of the first embodiment. The other configuration is identical to that of the first embodiment.

The delay control circuit 42 has a frequency divider 44, a latch 46, and a delay adjustment circuit 12. The frequency divider 44 divides the reference clock signal RCLK2 in frequency, and outputs the frequency-divided signal as a sampling clock signal SCLK. The latch 46 accepts the comparison result from the phase comparator 10 in synchronization with the sampling clock signal SCLK, and outputs the accepted information to the delay adjustment circuit 12. That is, the result of a single phase comparison among a plurality of phase comparisons is accepted into the latch 46.

The frequency divider 44 is rendered changeable in dividing rate by the pattern shape of the photomask used in the wiring process. More specifically, in the present embodiment, two photomasks with different pattern shapes are prepared in the wiring process. Then, the wiring process is performed with either of these photomasks to change the dividing rate of the frequency divider 44. For example, one of the photomasks is used to connect a predetermined conductive pattern of the frequency divider 44 to a power supply line; the other photomask is used to connect the same to a ground line. That is, these conductive patterns function as the comparison setting unit for setting the dividing rate of the frequency divider 44. Typically, conductive patterns can be constituted by traces of approximately several tens of micrometers in length. Thus, the adoption of the present embodiment will not cause any increase in chip size.

Incidentally, a register capable of being set from chip exterior may be formed on the SDRAM so that the dividing rate of the frequency divider 44 is changed in accordance with the set value of the register. Otherwise, a fuse circuit may be formed on the SDRAM so that the dividing rate of the frequency divider 44 is changed by means of fuse blowing.

This embodiment can offer the same effect as that obtained from the first embodiment. Furthermore, in this embodiment, the delay control circuit 42 adjusts the delay time of the variable delay circuit 4 corresponding to the comparison result synchronous to the sampling clock signal SCLK among the plurality of comparison results. Therefore, the delay time can be adjusted without forming the storing register 28, the control signal generating unit 30, and the like of the first embodiment.

Moreover, the frequency divider 44 is rendered changeable in dividing rate depending on the type of the photomask used in the wiring process. Therefore, the number of phase comparisons can be optimized in accordance with the operating frequency characteristics of SDRAMs to be shipped, allowing minimization of the jitter in the controlling clock signal CCLK. This is particularly effective when SDRAMs fabricated by using the same manufacturing processes, having a sufficient margin in the operating frequency are shipped as a plurality of products with different operating frequencies by means of photomask switching.

The embodiments described above have dealt with the cases where the present invention is applied to SDRAMs, which are memories of clock synchronous type. However, the present invention is not limited to such embodiments. For example, the present invention may be applied to microcomputers or logic LSIs such as a cell based IC. Moreover, the present invention may be applied to system LSIs that implement DRAM cores.

The third embodiment described above has dealt with the case where the number of phase comparisons is changed by fuses. However, the present invention is not limited to such an embodiment. For example, bonding pads for changing the number of comparisons may be formed in advance so that in the semiconductor assembly process, the bonding pads are connected to a power supply terminal or a ground terminal to change the number of comparisons. Incidentally, when the semiconductor package is a CSP (Chip Size Package), pads for bump connection are formed thereon.

The invention is not limited to the above embodiments and various modifications may be made without departing from the spirit and the scope of the invention. Any improvement may be made in part or all of the components.

What is claimed is:

1. A method for adjusting a phase of a controlling clock signal comprising the steps of:
generating said controlling clock signal for use in an internal circuit by delaying a reference clock signal by a predetermined time with a variable delay circuit;
generating a delayed clock signal by delaying said controlling clock signal by a predetermined time;
comparing said delayed clock signal and said reference clock signal in phase; and
adjusting the delay time of said variable delay circuit corresponding to a plurality of phase comparison results identical to one another, so as to have said delayed clock signal coincide with said reference clock signal in phase.

2. The method for adjusting a phase of a controlling clock signal according to claim 1, comprising the steps of:
outputting a lead or a delay in phase of said delayed clock signal to said reference clock signal in phase as said comparison result; and
adjusting the delay time of said variable delay circuit when said comparison results are all identical to one another.

3. The method for adjusting a phase of a controlling clock signal according to claim 1, comprising the steps of:
outputting any one of a lead, a delay, and a coincidence in phase of said delayed clock signal to said reference clock signal in phase as said comparison result; and
adjusting the delay time of said variable delay circuit when only one of said lead and said delay is included in said plurality of comparison results.

4. The method for adjusting a phase of a controlling clock signal according to claim 1, comprising the steps of:
outputting a lead or a delay in phase of said delayed clock signal to said reference clock signal in phase as said comparison results;
respectively counting the number of said leads and the number of said delays included in said plurality of comparison results; and
adjusting the delay time of said variable delay circuit corresponding to said number counted.

5. The method for adjusting a phase of a controlling clock signal according to claim 1, comprising the steps of:
generating a sampling clock signal by dividing said reference clock signal in frequency; and
adjusting the delay time of said variable delay circuit corresponding to one of said comparison results, which is synchronous to said sampling clock signal.

6. A semiconductor integrated circuit having a delay locked loop circuit, comprising:
a variable delay circuit for generating a controlling clock signal for use in an internal circuit by delaying a reference clock signal by a predetermined time;
a dummy circuit for generating a delayed clock signal by delaying said controlling clock signal by a predetermined time;
a phase comparator for comparing said delayed clock signal and said reference clock signal in phase; and
a delay control circuit for receiving a plurality of phase comparison results in sequence from said phase comparator, and adjusting the delay time of said variable delay circuit corresponding to the phase comparison results identical to one another.

7. The semiconductor integrated circuit having a delay locked loop circuit according to claim 6, wherein:
said phase comparator outputs a lead or a delay in phase of said delayed clock signal to said reference clock signal in phase as said comparison result; and
said delay control circuit comprises a plurality of holding parts for respectively holding said plurality of comparison results, and adjusts the delay time of said variable delay circuit when said comparison results held in said holding parts are all identical to one another.

8. The semiconductor integrated circuit having a delay locked loop circuit according to claim 7, further comprising a comparison setting unit for setting the number of holding parts capable of holding said comparison results, to a predetermined value.

9. The semiconductor integrated circuit having a delay locked loop circuit according to claim 6, wherein:
said phase comparator outputs any one of a lead, a delay, and a coincidence in phase of said delayed clock signal to said reference clock signal in phase as said comparison results; and
said delay control circuit comprises a plurality of holding parts for respectively holding said plurality of comparison results, and adjusts the delay time of said variable delay circuit when only one of said lead and said delay is included in said comparison results held in said delay control circuit.

10. The semiconductor integrated circuit having a delay locked loop circuit according to claim 9, further comprising a comparison setting unit for setting the number of holding parts capable of holding said comparison results, to a predetermined value.

11. The semiconductor integrated circuit having a delay locked loop circuit according to claim 10, wherein:
said comparison setting unit has a register set from an exterior; and
said predetermined value is changed in accordance with a value set in said register.

12. The semiconductor integrated circuit having a delay locked loop circuit according to claim 10, wherein:
said comparison setting unit has a fuse; and
said predetermined value is changed in response to a blowing of said fuse.

13. The semiconductor integrated circuit having a delay locked loop circuit according to claim 10, wherein:
said comparison setting unit has a conductive pattern, which is formed on a semiconductor substrate in conformity to the pattern shape of a photomask used in a fabrication process; and
said predetermined value is changed in accordance with a voltage of the destination of said conductive pattern.

14. The semiconductor integrated circuit having a delay locked loop circuit according to claim 6, wherein:
said phase comparator outputs a lead or a delay in phase of said delayed clock signal to said reference clock signal in phase as said comparison results;
said delay control circuit comprises counters for respectively counting the number of said leads and the number of said delays included in said plurality of comparison results; and
the delay time of said variable delay circuit is adjusted corresponding to the number counted.

15. The semiconductor integrated circuit having a delay locked loop circuit according to claim 14, further comprising a comparison setting unit for setting the number of comparison results, which is received by said delay control circuit, to a predetermined value, in order to perform a single adjustment of said delay time.

16. The semiconductor integrated circuit having a delay locked loop circuit according to claim 15, wherein:
said comparison setting unit has a register set from an exterior; and
said predetermined value is changed in accordance with a value set in said register.

17. The semiconductor integrated circuit having a delay locked loop circuit according to claim 15, wherein:
said comparison setting unit has a fuse; and
said predetermined value is changed in response to a blowing of said fuse.

18. The semiconductor integrated circuit having a delay locked loop circuit according to claim 15, wherein:
said comparison setting unit has a conductive pattern, which is formed on a semiconductor substrate in conformity to the pattern shape of a photomask used in a fabrication process; and
said predetermined value is changed in accordance with a voltage of the destination of said conductive pattern.

19. The semiconductor integrated circuit having a delay locked loop circuit according to claim 6, wherein said delay control circuit:
comprises a frequency divider for dividing said reference clock signal in frequency to generate a sampling clock signal; and
adjusts the delay time of said variable delay circuit corresponding to one of said comparison results, which is synchronous to said sampling clock signal.

20. The semiconductor integrated circuit having a delay locked loop circuit according to claim 19, further comprising a comparison setting unit for setting a dividing rate of said frequency divider to a predetermined value.

21. The semiconductor integrated circuit having a delay locked loop circuit according to claim 20, wherein:
said comparison setting unit has a register set from an exterior; and
said predetermined value is changed in accordance with a value set in said register.

22. The semiconductor integrated circuit having a delay locked loop circuit according to claim 20, wherein:
said comparison setting unit has a fuse; and
said predetermined value is changed in response to a blowing of said fuse.

23. The semiconductor integrated circuit having a delay locked loop circuit according to claim 20, wherein:
said comparison setting unit has a conductive pattern, which is formed on a semiconductor substrate in conformity to the pattern shape of a photomask used in a fabrication process; and
said predetermined value is changed in accordance with a voltage of the destination of said conductive pattern.
